(19) United States
(12) Patent Application Publication
(10) Pub. No.: US 2026/0190768 A1
(43) Pub. Date: Jul. 2, 2026

(54) DISPLAY DEVICE

(71) Applicant: LG DISPLAY CO., LTD., SEOUL (KR)

(72) Inventors: Heeyeon Hwang, Hanam-si (KR); SangHoon Oh, Seoul (KR)

(21) Appl. No.: 19/429,577

(22) Filed: Dec. 22, 2025

(30) Foreign Application Priority Data
Dec. 31, 2024 (KR) 10-2024-0201799

(51) Int. Cl. H10K 59/80; H05K 1/189; H10K 59/12; H10K 102/00

(52) U.S. Cl. CPC H10K 59/8722; H05K 1/189; H10K 59/1201; H05K 2201/10128; H10K 2102/311

(57) ABSTRACT

A display device includes a display panel including a first area, a bending area around the first area, and a second area extending from the bending area, a first back plate disposed below the display panel in the first area and in the bending area, a second back plate spaced apart from the first back plate and disposed below the first back plate in the bending area and in the second area, a flexible circuit board disposed below the display panel in the bending area and in the second area, a plurality of dams disposed on the flexible circuit board, and a reinforcement member disposed between the plurality of dams on the flexible circuit board. Accordingly, it is possible to reduce deformation of the bending area due to external impact.

### CROSS-REFERENCE TO RELATED APPLICATIONS

Pursuant to 35 U.S.C. § 119(a), this application claims the benefit of an earlier filing date and right of priority to Korean Patent Application No. 10-2024-0201799 filed on December 31, 2024, in the Korean Intellectual Property Office, the disclosure of which is incorporated herein by reference in its entirety.

### TECHNICAL FIELD

The present disclosure generally relates to a display device.

### BACKGROUND

Display devices are implemented in a wide variety of forms such as televisions, monitors, smartphones, tablet PCs, laptops, and wearable devices. In general, a cover glass is formed on the front surface of the display device, and the user may recognize the display screen through the cover glass. In this case, the cover glass generally has a flat shape, but in recent years, the demand for a curved display device having a curved edge portion in which the edge portion of the cover glass is bent has increased. In the curved display device, a screen may be recognized through a cover glass even along one or more side surfaces of the display device, thereby obtaining an effect of expanding a substantial screen size.

### SUMMARY

A display device according to an example implementation of the present disclosure includes a display panel including a first area, a bending area around the first area, and a second area extending from the bending area, a first back plate disposed below the display panel in the first area and in the bending area, a second back plate spaced apart from the first back plate and disposed below the first back plate in the bending area and in the second area, a flexible circuit board disposed below the display panel in the bending area and in the second area, a plurality of dams disposed on the flexible circuit board, and a reinforcement member disposed between the plurality of dams on the flexible circuit board.

Implementations disclosed herein can provide various technical effects, examples of which are described below.

Implementations of the present disclosure can help reduce deformation of the bending area due to external impact.

According to some implementations of the present disclosure, by disposing the reinforcement member in the bending area, it is possible to minimize damage to the bending area due to external impact.

According to some implementations of the present disclosure, a plurality of dams are disposed on the flexible circuit board to accommodate the reinforcement member, thereby preventing overflow of the reinforcement member.

According to some implementations of the present disclosure, the lifespan of the display device is improved by minimizing a potential defect caused by an external impact, so that the display device may be driven with low power in terms of reducing production energy.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view of a display device according to an implementation.

FIG. 2 is a cross-sectional view taken along the line II-II' of FIG. 1.

FIG. 3A is a cross-sectional view of a display device according to an implementation.

FIG. 3B is a perspective view of a display device according to an implementation.

FIGS. 4A to 4F are process diagrams of a method of manufacturing a display device according to an example implementation.

FIG. 5A is a perspective view of a display device according to another implementation.

FIG. 5B is a cross-sectional view of a display device according to another implementation.

FIG. 6 is a cross-sectional view of a display device according to still another implementation.

FIG. 7 is a cross-sectional view of a display device according to another implementation.

FIG. 8 is a cross-sectional view of a display device according to still another implementation.

FIG. 9 is a cross-sectional view of a display device according to still another implementation.

FIG. 10 is a cross-sectional view of a display device according to another implementation.

### DETAILED DESCRIPTION

Implementations of the present disclosure can provide a display device in which deformation of a bending area due to external impact is minimized.

Implementations of the present disclosure can provide a display device in which a reinforcement member is disposed in an empty space in a bending area to absorb an external impact.

Implementations of the present disclosure can provide a display device in which deformation of a bending area due to an external impact is minimized.

Implementations of the present disclosure can provide a display device in which a dam is disposed on a flexible circuit board to minimize an overflow of a reinforcement member.

Objects of the present disclosure are not limited to the above-mentioned objects, and other objects, which are not mentioned above, can be clearly understood by those skilled in the art from the following descriptions.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various implementations of the present disclosure can be partially or entirely adhered to or combined with each other and can be interlocked and operated in technically various ways, and the implementations can be carried out independently of or in association with each other.

Hereinafter, example implementations of the present disclosure will be described in detail with reference to accompanying drawings.

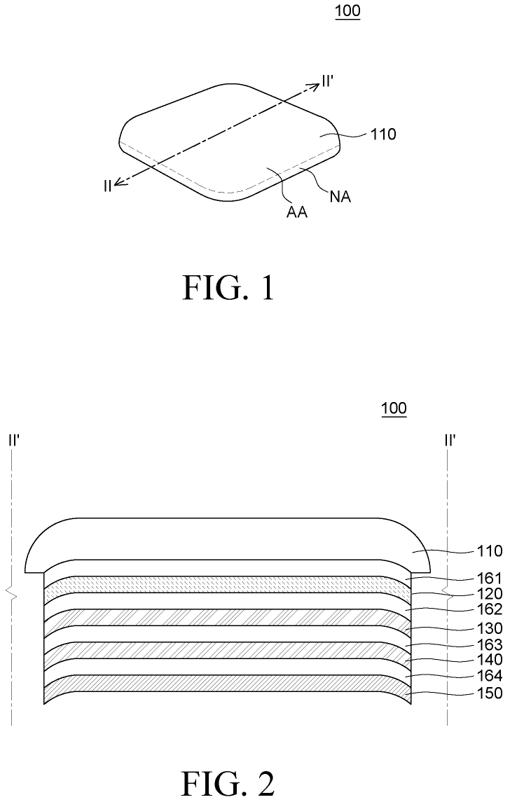

FIG. 1 is a perspective view of a display device according to an implementation. FIG. 2 is a cross-sectional view taken along the line II-II' of FIG. 1. In FIG. 1, for the convenience of illustration, among various components of the display device 100, only a cover glass 110 is illustrated.

Referring to FIGS. 1 and 2, a display device 100 according to an implementation may include a cover glass 110, a first adhesive layer 161, a polarization layer 120, a second adhesive layer 162, a display panel 130, a third adhesive layer 163, a back plate 140, a fourth adhesive layer 164, and a metal plate 150.

Referring to FIGS. 1 and 2, the cover glass 110 may be bent in a curved shape having a preset radius of curvature from all edge portions. Accordingly, the edge portion of the cover glass 110 may have a structure that is bent as a whole. For example, the cover glass 110 has a four-sided bending structure that is bent as a whole to improve the aesthetics of the display device and reduce the bezel width in each of the long side direction and the short side direction of the display device.

The polarization layer 120 may be disposed below the cover glass 110. The polarization layer 120 is a layer for polarizing incident light, and is a film having a predetermined level of light transmittance to absorb external light and reflected light thereof to prevent a decrease in contrast ratio. Therefore, the degradation of the display quality of the display device 100 due to the reflected light reflected by the external light may be prevented, and the transmittance of the image of the display device 100 may be improved.

The first adhesive layer 161 may be disposed between the cover glass 110 and the polarization layer 120. The first adhesive layer 161 may adhere the cover glass 110 and the polarization layer 120 to fix the cover glass 110 and the polarization layer 120 to each other. The first adhesive layer 161 may be, for example, an optically clear adhesive (OCA), but is not limited thereto.

The display panel 130 may be disposed below the polarization layer 120. The display panel 130 may include various components including a substrate and a light emitting element.

The substrate is a support member for supporting other components disposed on the substrate of the display device 100 and may be made of an insulating material. For example, the substrate may be made of glass or resin.

In addition, the substrate may include plastic such as polymer or polyimide (PI) or may be made of a material having flexibility.

A light emitting element may be disposed on the substrate. The light emitting element may be differently defined depending on the type of the display panel 130. When the display panel 130 is, for example, an organic light emitting display panel, the light emitting element may be an organic light emitting diode (OLED).

A transistor for driving the light emitting element may be disposed between the substrate and the light emitting element. The transistor may be disposed in each of the plurality of sub-pixel areas.

A second adhesive layer 162 may be disposed between the polarization layer 120 and the display panel 130. The second adhesive layer 162 may bond and fix the polarization layer 120 and the display panel 130. For example, the second adhesive layer 162 may be an optically clear adhesive (OCA), but is not limited thereto.

The back plate 140 may be disposed below the display panel 130. The back plate 140 supports the display panel 130 and may protect the display panel 130 from external moisture, heat, impact, and the like. For example, the back plate 140 may be a metal material such as stainless steel (SUS) or Invar, or may be formed of plastic such as polymethylmetacrylate (PMMA), polycarbonate (PC), polyvinylalcohol (acrylonitrile-styrene (PVA), ABS), acrylonitrile-butadiene-styrene polyethylene terephthalate (PET), silicone, or polyurethane (PU), but is not limited thereto. As described below, the back plate 140 may include a first back plate 141 and a second back plate 142.

A third adhesive layer 163 may be disposed between the display panel 130 and the back plate 140. The third adhesive layer 163 may bond and fix the display panel 130, the first back plate 141, and the second back plate 142. The third adhesive layer 163 may include a variable adhesive material that facilitates re-peeling and easy removal of a local portion. For example, the third adhesive layer 163 may be a variable adhesive layer whose adhesive force varies according to a specific condition. Accordingly, after attaching the initial back plate to the display panel 130 using the third adhesive layer 163, after removing the area to be removed through the half-cut process, the third adhesive layer 163 may be heated to improve adhesion. Accordingly, as will be described below, not only the first back plate and the second back plate may be easily formed, but also the opening of the second back plate may be easily formed.

The metal plate 150 may be disposed below the back plate 140. The metal plate 150 may include a conductive material having high thermal conductivity. Accordingly, the metal plate 150 may perform a ground function together with a heat dissipation function and protect the rear surface of the display panel 130. The metal plate 150 may be formed of various conductive materials, for example, a material including aluminum (Al) or copper (Cu), but is not limited thereto.

A fourth adhesive layer 164 may be disposed between the back plate 140 and the metal plate 150. The fourth adhesive layer 164 may bond and fix the back plate 140 and the metal plate 150. For example, the fourth adhesive layer 164 may be a pressure sensitive adhesive (PSA), but is not limited thereto.

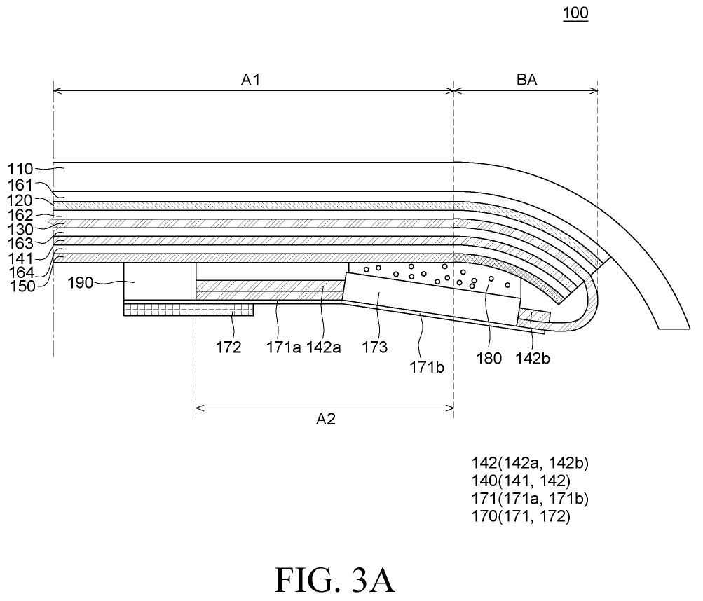

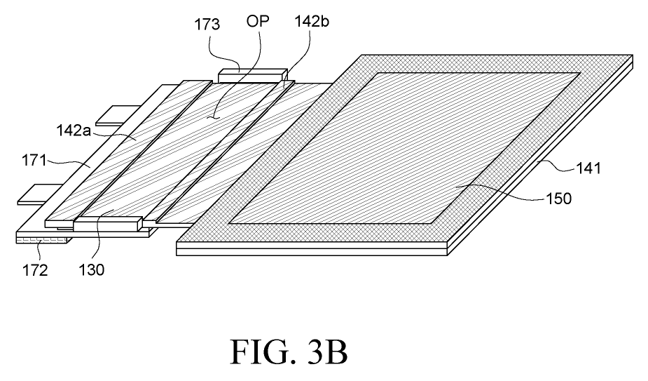

FIG. 3A is a cross-sectional view of a display device according to an implementation. FIG. 3B is a perspective view of a display device according to an implementation. In FIGS. 3A and 3B, for convenience of illustration, adhesive layers disposed between the second back plate 142 and the display panel 130 and between the display panel 130 and the flexible circuit board (FPCB) 170 is omitted. Further, in FIG. 3B, among various components of the display device 100, only the display panel 130, the back plate 140, the flexible circuit board 170, and the metal plate 150 are illustrated.

Referring to FIG. 3A, the display panel 130 may define a first area A1, a bending area BA around the first area A1, and a second area A2 extending from the bending area BA.

For example, the first area A1 may be a flat area. In addition, the first area A1 may include a display area AA in which an image is displayed and a non-display area NA in which an image is not displayed. In the display area AA, a plurality of sub-pixels constituting a plurality of pixels and a circuit for driving the plurality of sub-pixels may be disposed.

The bending area BA can be an area surrounding the first area A1, and may be an area that is bent to minimize or reduce the bezel area. For example, the bending area BA can bend to form a rounded edge of the display panel 130. Like the first area A1, the bending area BA may include not only the display area AA, but also the non-display area NA.

The second area A2 is an area extending from the bending area BA and may be disposed below the first area A1. The second area A2 may be a non-display area NA in which no image is displayed. For example, the second area A2 may extend from a portion of the bending area BA that has wrapped around the edge of the display panel 130 to be disposed below the first area A1.

The flexible circuit board 170 may be disposed on the display panel 130. The flexible circuit board 170 is configured to supply a signal to the driving IC.

The flexible circuit board 170 may include a base substrate 171. The base substrate 171 is a support member for supporting various components disposed on the base substrate 171 and may be formed of an insulating material. For example, the base substrate 171 may include plastic such as polymer or polyimide (PI) and may be made of a material having flexibility, but is not limited thereto.

The base substrate 171 may include a first part 171a on which a driving circuit is disposed, and a second part 171b which extends from the first part 171a and on which a driving circuit is not disposed. Various components, for example, the driver IC 172, and the like for supplying various driving signals, such as a driving signal and a data voltage, to the driving IC may be disposed on the first part 171a of the base substrate 171.

Referring to FIG. 3B together, a plurality of dams 173 may be disposed on the second part 171b of the base substrate 171. A plurality of dams 173 may be disposed on two sides facing each other of the base substrate 171. A plurality of dams 173 may be disposed on two sides facing each other in a length direction of the base substrate 171. Specifically, the plurality of dams 173 may be disposed to face each other in a direction perpendicular to the bending direction of the bending area BA. The plurality of dams 173 may be disposed to surround the side surface of the display panel 130 to protect and support the display panel 130, and may be disposed to surround the reinforcement member 180 together with the second back plate 142 to be described below to control the arrangement area of the reinforcement member 180. Accordingly, overflow of the reinforcement member 180 may be prevented. For example, the plurality of dams 173 may serve as guide members for guiding the arrangement region of the reinforcement member 180.

Specifically, the thickness of each of the plurality of dams 173 may be greater than the sum of the thicknesses of the display panel 130 and the second back plate 142. Accordingly, the plurality of dams 173 is disposed so as to enclose at least a part of the reinforcement member 180 disposed in an opening OP of the second back plate 142, for example, disposed on the display panel 130, to control the arrangement area of the reinforcement member 180.

Meanwhile, the plurality of dams 173 may be formed of a rigid material to minimize overexpansion of the reinforcement member 180. For example, the plurality of dams 173 may be formed of a plastic material, but is not limited thereto.

The back plate 140 may include a first back plate 141 disposed in the first area A1 and the bending area BA, and a second back plate 142 spaced apart from the first back plate 141 and disposed in the bending area BA and the second area A2.

An opening OP exposing the display panel 130 may be formed in the second back plate 142. Therefore, the second back plate 142 may include a 2-1 back plate 142a and a 2-2 back plate 142b which are disposed to be spaced apart from each other with respect to the opening OP.

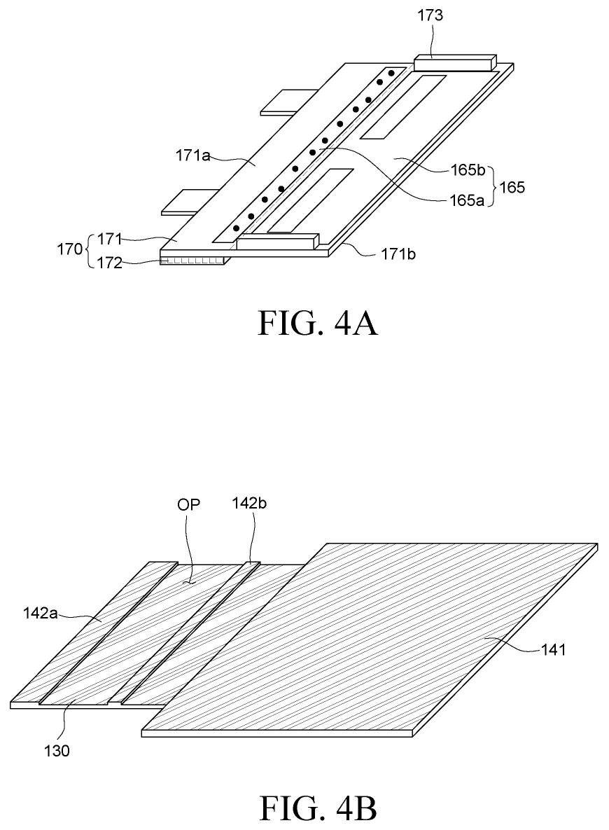

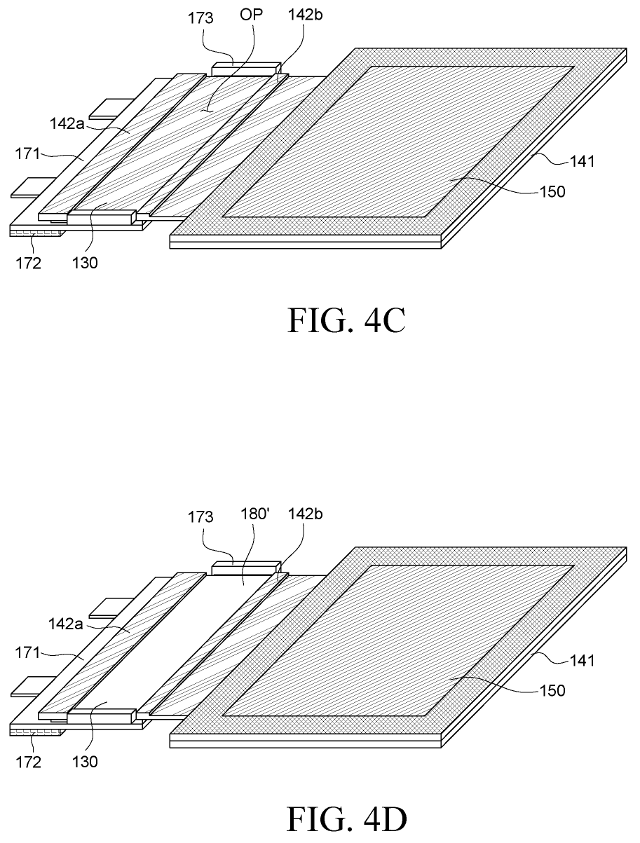

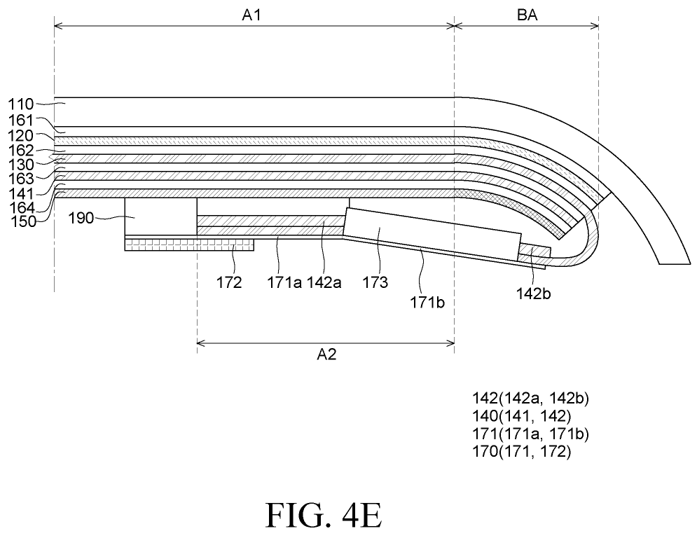

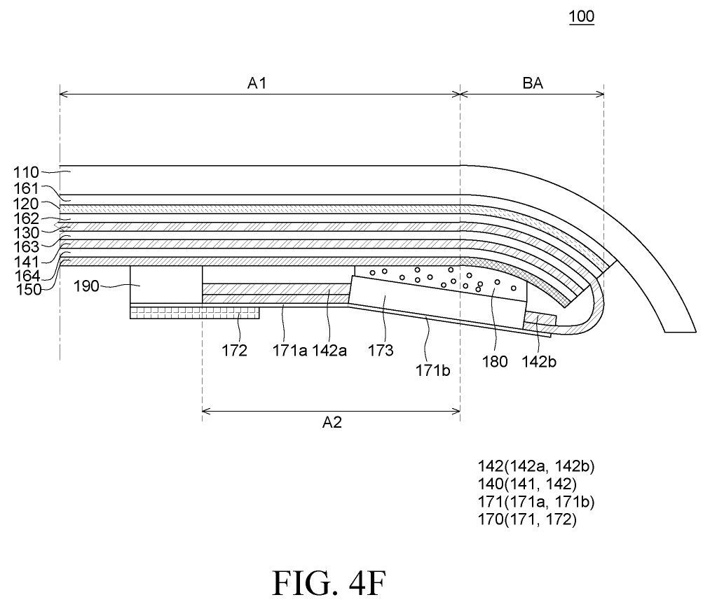

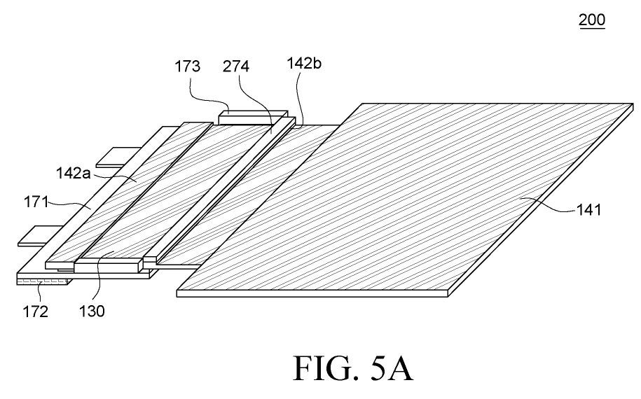

The opening OP accommodates the reinforcement member 180 to control an arrangement region of the reinforcement member 180 together with the plurality of dams 173 to prevent overflow of the reinforcement member 180. Specifically, the opening OP may be disposed to overlap the flexible circuit board 170 in the bending area BA and the second area A2. In this case, the opening OP may be disposed between a plurality of dams 173. For example, a width of the opening OP of the second back plate 142 may be equal to a gap between the plurality of dams 173. Accordingly, the reinforcement member 180 disposed in the opening OP may be surrounded by the second back plate 142 and the plurality of dams 173. Details related to this will be described in detail with reference to FIGS. 4A to 4F to be described later.

The reinforcement member 180 may be disposed in the opening OP. Specifically, the reinforcement member 180 may be disposed in an area between a plurality of dams 173. The reinforcement member 180 may be applied to the inside of the plurality of dams 173 and then foamed to fill the bending area BA and the second area A2. Accordingly, the reinforcement member 180 may absorb an external impact through the pores formed during the foaming process. Accordingly, the reinforcement member 180 may be formed of a microcapsule-type foaming agent to be foamed to form pores. For example, the reinforcement member 180 may be formed of a material including a liquid hydrocarbon inside a shell of a thermoplastic resin, but is not limited thereto.

In this case, the reinforcement member 180 is disposed in an area partitioned by the opening OP and the plurality of dams 173 so that the reinforcement member 180 may be disposed only in a partial area of the bending area BA and the second area A2. In particular, the reinforcement member 180 may be disposed only in a part of the bending area BA. For example, when the reinforcement member 180 is disposed in the entire bending area BA, the bending stress may be increased by expansion and foaming of the reinforcement member 180. Accordingly, the reinforcement member 180 is disposed only in a partial area of the bending area BA to minimize an increase in the bending stress.

Meanwhile, the reinforcement member 180 may be formed to be higher than the plurality of dams 173 by foaming and expanding. Accordingly, the reinforcement member 180 may be in contact with the rear surface of the metal plate 150 unlike dam 173, but is not limited thereto.

Meanwhile, the metal plate 150 may include an opening pattern disposed in the bending area BA. Since the metal plate 150 is made of a metal material and has rigidity, the metal plate 150 may be easily bent by forming an opening pattern in the bending area BA.

The foam tape 190 may be disposed under the metal plate 150. The foam tape 190 may be disposed between the metal plate 150 and the flexible circuit board 170 to bond and fix the metal plate 150 and the flexible circuit board 170.

Hereinafter, a method of manufacturing a display device according to an implementation will be described with reference to FIGS. 4A to 4F together.

FIGS. 4A to 4F are process diagrams of a method of manufacturing a display device according to an example implementation.

First, referring to FIG. 4A, a plurality of dams 173 may be disposed on the base substrate 171. A plurality of dams 173 may be disposed on two opposite sides of the second part 171b of the base substrate 171. A plurality of dams 173 may be disposed on two sides facing each other in a length direction of the base substrate 171. Specifically, the plurality of dams 173 may be disposed in a direction perpendicular to the bending direction of the bending area BA.

In this case, the width of the long side of the plurality of dams 173 may be determined according to the application amount of the reinforcement member 180. For example, a width of a long side of the plurality of dams 173 may be 5 mm to 7 mm, but is not limited thereto.

The width of the short side of the plurality of dams 173 may be determined within a range that does not invade the display area AA. For example, the width of the short side of the plurality of dams 173 may be 2 mm to 5 mm, but is not limited thereto.

The height of the plurality of dams 173 may be determined not to contact the metal plate 150. For example, the plurality of dams 173 may be disposed to be spaced apart from the rear surface of the metal plate 150. For example, the plurality of dams 173 may be designed to have a height of 1 mm or less, but is not limited thereto.

Meanwhile, a fifth adhesive layer 165 for bonding the flexible circuit board 170 and the display panel 130 may be disposed on the base substrate 171. The fifth adhesive layer 165 may include a fifth-first adhesive layer 165a and a fifth-second adhesive layer 165b made of different materials. For example, the fifth-first adhesive layer 165a may be disposed on the first part 171a of the base substrate 171, for example, a part on which a driving circuit is disposed. Therefore, since the fifth-first adhesive layer 165a requires a conductive property to electrically connect the driving circuit of the flexible circuit board 170 and the display panel 130, the fifth-first adhesive layer 165a may be formed of a conductive adhesive film. In contrast, the fifth-second adhesive layer 165b may be disposed on the second part 171b of the base substrate 171, for example, a part on which the driving circuit is not disposed. Therefore, the fifth-second adhesive layer 165b may be formed of an adhesive material without conductivity because conductive properties are unnecessary, but is not limited thereto.

Next, referring to FIG. 4B, the back plate 140 and the display panel 130 may be fixed using the third adhesive layer 163 (see FIG. 3A). Since the third adhesive layer 163 is a variable adhesive, the first back plate 141, the second back plate 142, and the opening OP may be formed by partially removing the initial back plate through a half-cut process after attaching the initial back plate and the display panel 130 using the third adhesive layer 163.

Specifically, since the third adhesive layer 163 is a variable adhesive, the initial adhesive force may be relatively low. For example, the third adhesive layer 163 may include an anti-stick agent. The anti-stick agent may be coated to be disposed close to one surface of the third adhesive layer 163. For example, the anti-stick agent may be disposed close to one surface of the third adhesive layer 163 which is in contact with the back plate 140 which is an adherend. Therefore, the initial adhesive force between the third adhesive layer 163 and the back plate 140 may be relatively low. Accordingly, a process of removing a part of the initial backplate through the half-cut process may be easily performed.

Next, when the third adhesive layer 163 is heated, the anti-adhesive agent disposed on one surface of the third adhesive layer 163 may move and be dispersed into the third adhesive layer 163. Accordingly, the number of anti-stick agents distributed on one surface of the third adhesive layer 163 in contact with the back plate 140 may be significantly reduced. Accordingly, the natural adhesive force of the third adhesive layer 163 may be exhibited. Accordingly, the third adhesive layer 163 may fix the back plate 140 and the display panel 130.

Next, referring to FIG. 4C, the flexible circuit board 170 may be bonded to the display panel 130. In this case, the flexible circuit board 170 may be bonded so that the opening OP of the second back plate 142 is disposed between the dams 173. Therefore, the base substrate 171 is disposed to overlap the opening OP to serve to protect the display panel 130 exposed by the opening OP.

Next, referring to FIG. 4C, the metal plate 150 may be disposed on the first back plate 141, and the polarization layer 120 (see FIG. 3A) may be disposed on the display panel 130 to form a display module.

Subsequently, referring to FIG. 4D, a reinforcement member material layer 180′ may be applied to an area between the opening OP and the plurality of dams 173.

Next, referring to FIG. 4E, the display module to which the reinforcement member material layer 180′ is applied may be coupled to the cover glass 110, and a part of the display module may be bent. For example, a portion of the display panel 130, which does not overlap the back plate 140, for example, a portion corresponding to an area between the first back plate 141 and the second back plate 142 may be bent. Specifically, a portion of the display panel 130 overlapping the second back plate 142 may be bent to be disposed under a portion of the display panel 130 overlapping the first back plate 141. Accordingly, the metal plate 150 and the dam 173 may be disposed to face each other as shown in FIG. 4F to be described later.

Next, referring to FIG. 4F, the reinforcement member 180 may be formed by applying heat to the reinforcement member material layer 180′ to expand and foam. In this case, the plurality of dams 173 controls the arrangement region of the reinforcement member 180 to prevent over-expansion of the reinforcement member 180. Meanwhile, the pores formed by the expansion of the reinforcement member 180 may absorb an external impact to prevent the bending area BA from being deformed.

The bezel area is bent below the display area to minimize the bezel area visually recognized by the user.

In this case, in the case of the display device having four curved surfaces, the bending stress may be further increased in the bending area as the curvature direction of the four surfaces and the curvature direction of the bending area are changed. In particular, when there is an empty space in the bending area, a change in the bending curvature may occur relatively large. For example, in this case, an inflection point is generated in the radius of curvature, and may be vulnerable to impact due to bending stress.

Therefore, in the display device 100, the reinforcement member 180 may be disposed in the bending area BA. For example, the reinforcement member 180 fills the empty space of the bending area BA so that the bending stress according to the difference between the curvature direction of the four surfaces and the curvature direction of the bending area BA may be alleviated. In this case, the reinforcement member 180 may be formed of a foaming agent including a plurality of pores. Accordingly, it is possible to minimize the deformation of the bending area BA by absorbing an external impact through a plurality of pores.

Further, in the display device 100, a plurality of dams 173 for guiding the reinforcement member 180 may be disposed on the flexible circuit board 170. For example, the dam 173 controls the arrangement region of the reinforcement member 180 to minimize the overflow and overexpansion of the reinforcement member 180. In this case, the dam 173 may be disposed only in a part of the bending area BA. Accordingly, the reinforcement member 180 may also be disposed only in a part of the bending area BA. For example, in the display device 100 according to the example implementation of the present disclosure, while minimizing the occurrence of an inflection point in the radius of curvature as the reinforcement member 180 partially fills the empty space of the bending area BA, the reinforcement member 180 is not disposed in the entire bending area BA to prevent the bending stress from increasing.

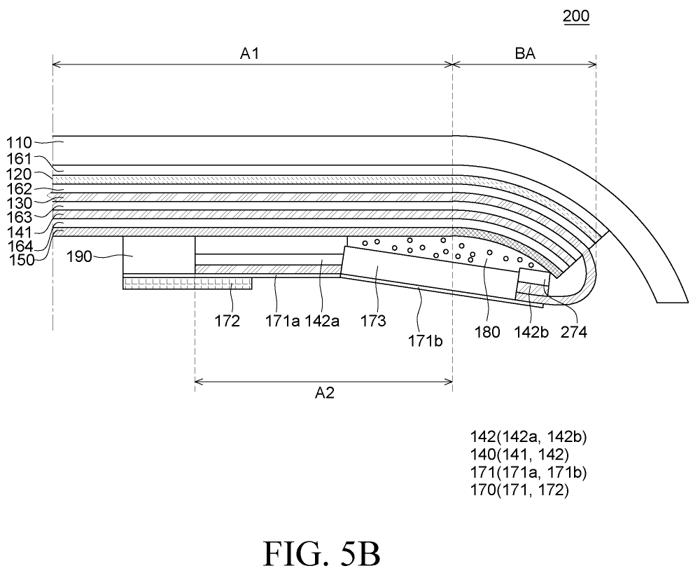

FIG. 5A is a perspective view of a display device according to another implementation of the present disclosure. FIG. 5B is a cross-sectional view of a display device according to another implementation of the present disclosure. The only difference between a display device 200 of FIGS. 5A and 5B and the display device 100 of FIGS. 3A and 3B is the presence or absence of an auxiliary dam 274, but other components are substantially the same, so that a redundant description will be omitted. In FIG. 5A, for the convenience of illustration, among various components of the display device 200, only a display panel 130, a back plate 140, and a flexible circuit board 170 are illustrated.

Referring to FIGS. 5A and 5B, an auxiliary dam 274 may be disposed on the second back plate 142. Specifically, the auxiliary dam 274 may be disposed on the 2-2 back plate 142b disposed in the bending area BA of the second back plate 142. The auxiliary dam 274 is formed to have the same width as the width of the 2-2 back plate 142b to prevent the reinforcement member 180 from overflowing to the outside of the 2-2 back plate 142b.

Further, a top surface of the auxiliary dam 274 may be in contact with a rear surface of the metal plate 150. Accordingly, it is possible to more effectively block the reinforcement member 180 from flowing from the bending area BA to the outside of the area in which the dam 173 is disposed. Accordingly, the auxiliary dam 274 may minimize the increase in bending stress due to the over-spread or over-expansion of the reinforcement member 180 in the bending area BA.

In the display device 200 according to another implementation, the reinforcement member 180 may be disposed in the bending area BA. For example, the reinforcement member 180 fills the empty space of the bending area BA so that the bending stress according to the difference between the curvature direction of the four surfaces and the curvature direction of the bending area BA may be alleviated. In this case, the reinforcement member 180 may be formed of a foaming agent including a plurality of pores. Accordingly, it is possible to minimize the deformation of the bending area BA by absorbing an external impact through a plurality of pores.

Further, in the display device 200 according to another implementation, a plurality of dams 173 for guiding the reinforcement member 180 may be disposed on the flexible circuit board 170. For example, the dam 173 controls the arrangement region of the reinforcement member 180 to minimize the overflow and over-expansion of the reinforcement member 180. In this case, the dam 173 may be disposed only in a part of the bending area BA. Accordingly, the reinforcement member 180 may also be disposed only in a part of the bending area BA. For example, in the display device 200 according to another example implementation of the present disclosure, while minimizing the occurrence of an inflection point in the radius of curvature as the reinforcement member 180 partially fills the empty space of the bending area BA, the reinforcement member 180 is not disposed in the entire bending area BA, thereby preventing an increase in bending stress due to over-expansion.

In particular, in the display device 200 according to another implementation, the auxiliary dam 274 may be disposed on the second back plate 142. The auxiliary dam 274 is disposed in the bending area BA to control the arrangement area of the reinforcement member 180 together with the dam 173, thereby minimizing overflow and over-expansion of the reinforcement member 180. In particular, the auxiliary dam 274 may be disposed such that an top surface thereof is in contact with the rear surface of the metal plate 150. Therefore, it is possible to more effectively control the arrangement area of the reinforcement member 180 by blocking the reinforcement member 180 from flowing from the bending area BA to the outside of the area in which the dam 173 is disposed.

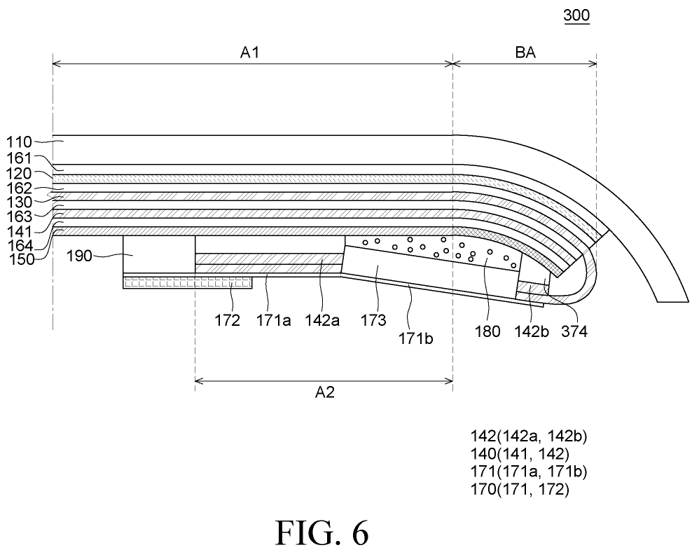

FIG. 6 is a cross-sectional view of a display device according to still another example implementation of the present disclosure. The only difference between a display device 300 of FIG. 6 and the display device 200 of FIGS. 5A to 5B is a shape of an auxiliary dam 374, but other components are substantially the same, so that a redundant description will be omitted.

Referring to FIG. 6, an auxiliary dam 374 may be disposed on the second back plate 142. Specifically, the auxiliary dam 374 may be disposed on the 2-2 back plate 142b disposed in the bending area BA of the second back plate 142. The auxiliary dam 374 is formed to have the same width as the width of the 2-2 back plate 142b to prevent the reinforcement member 180 from overflowing to the outside of the 2-2 back plate 142b.

Further, a top surface of the auxiliary dam 374 may be in contact with a rear surface of the metal plate 150. In particular, the top surface of the auxiliary dam 374 may be formed of a curved surface. In this case, a radius of curvature of the top surface of the auxiliary dam 374 may be the same as a radius of curvature of the bending area BA. For example, the radius of curvature of the rear surface of the metal plate 150 disposed in the bending area BA is also the same as the radius of curvature of the bending area BA so that the top surface of the auxiliary dam 374 may be disposed to be engaged with the rear surface of the metal plate 150. Accordingly, it is possible to more effectively block the reinforcement member 180 from flowing from the bending area BA to the outside of the area in which the dam 173 is disposed. Accordingly, the auxiliary dam 374 may minimize an increase in bending stress due to the over-spread or over-expansion of the reinforcement member 180 in the bending area BA.

In the display device 300 according to still another example implementation, the reinforcement member 180 may be disposed in the bending area BA. For example, the reinforcement member 180 fills the empty space of the bending area BA so that the bending stress according to the difference between the curvature direction of the four surfaces and the curvature direction of the bending area BA may be alleviated. In this case, the reinforcement member 180 may be formed of a foaming agent including a plurality of pores. Accordingly, it is possible to minimize the deformation of the bending area BA by absorbing an external impact through a plurality of pores.

Further, in the display device 300 according to still another example implementation, a plurality of dams 173 for guiding the reinforcement member 180 may be disposed on the flexible circuit board 170. For example, the dam 173 controls the arrangement region of the reinforcement member 180 to minimize the overflow and the over-expansion of the reinforcement member 180. In this case, the dam 173 may be disposed only in a part of the bending area BA. Accordingly, the reinforcement member 180 may also be disposed only in a part of the bending area BA. For example, in the display device 300 according to still another example implementation, while minimizing the occurrence of an inflection point in the radius of curvature as the reinforcement member 180 partially fills the empty space of the bending area BA, the reinforcement member 180 is not disposed in the entire bending area BA, thereby preventing an increase in bending stress due to over-expansion.

In particular, in the display device 300 according to still another implementation, the auxiliary dam 374 may be disposed on the second back plate 142. The auxiliary dam 374 is disposed in the bending area BA to control the arrangement area of the reinforcement member 180 together with the dam 173, thereby minimizing overflow and over-expansion of the reinforcement member 180. In particular, the top surface of the auxiliary dam 374 may be formed of a curved surface having a radius of curvature equal to that of the bending area BA. Therefore, the rear surface of the metal plate 150 disposed in the bending area BA and the top surface of the auxiliary dam 374 may be disposed to be engaged with each other. Accordingly, it is possible to more effectively control the arrangement area of the reinforcement member 180 by blocking the reinforcement member 180 from flowing from the bending area BA to the outside of the area in which the dam 173 is disposed.

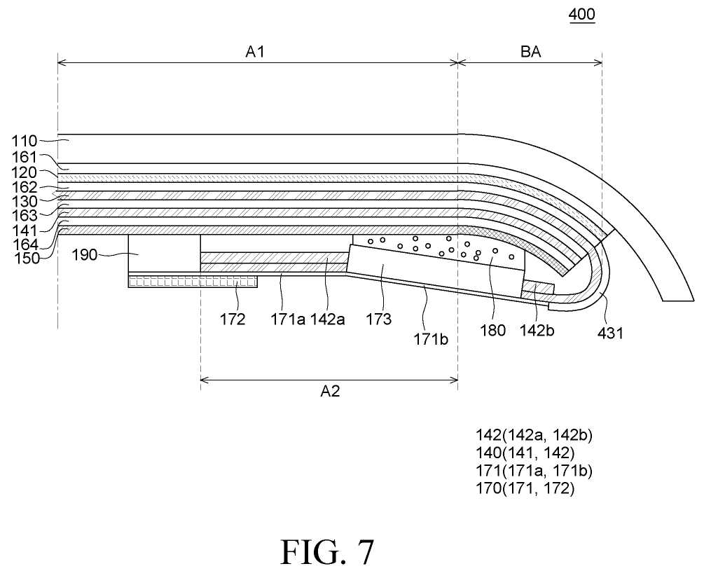

FIG. 7 is a cross-sectional view of a display device according to another implementation. The only difference between a display device 400 of FIG. 7 and the display device 100 of FIGS. 3A and 3B is the presence or absence of a buffer member 431, but other components are substantially the same, so that a redundant description will be omitted.

Referring to FIG. 7, a buffer member 431 may be disposed on the display panel 130 in the bending area BA. The buffer member 431 may be disposed in an area of the display panel 130 that does not overlap the back plate 140 to protect the display panel 130 instead of the back plate 140. Accordingly, the buffer member 431 may be disposed in an area between the first back plate 141 and the second back plate 142.

The buffer member 431 may be formed of a foam material having a plurality of pores to absorb an external impact. The buffer member 431 may be formed of, for example, polyurethane foam, but is not limited thereto.

Meanwhile, unlike the reinforcement member 180, the buffer member 431 may be formed of foam in a state in which the foam has already been expanded, rather than a post-foam type. Therefore, it is possible to minimize the excessive thickening of the bending area BA as the buffer member 431 disposed in the bending area BA is excessively expanded by the post-foaming. Further, the buffer member 431 may be formed of a material having a modulus lower than that of the reinforcement member 180. Accordingly, it may be disposed to more easily surround the curved surface of the bent display panel 130.

In the display device 400 according to still another example implementation, the reinforcement member 180 may be disposed in the bending area BA. For example, the reinforcement member 180 fills the empty space of the bending area BA so that the bending stress according to the difference between the curvature direction of the four surfaces and the curvature direction of the bending area BA may be alleviated. In this case, the reinforcement member 180 may be formed of a foaming agent including a plurality of pores. Accordingly, it is possible to minimize the deformation of the bending area BA by absorbing an external impact through a plurality of pores.

Further, in the display device 400 according to still another example implementation, a plurality of dams 173 for guiding the reinforcement member 180 may be disposed on the flexible circuit board 170. For example, the dam 173 controls the arrangement region of the reinforcement member 180 to minimize the overflow and the over-expansion of the reinforcement member 180. In this case, the dam 173 may be disposed only in a part of the bending area BA. Accordingly, the reinforcement member 180 may also be disposed only in a part of the bending area BA. For example, in the display device 400 according to still another example implementation, while minimizing the occurrence of an inflection point in the radius of curvature as the reinforcement member 180 partially fills the empty space of the bending area BA, the reinforcement member 180 is not disposed in the entire bending area BA, thereby preventing an increase in bending stress due to over-expansion.

In particular, in the display device 400 according to still another example implementation, the buffer member 431 may be disposed on the display panel 130 in the bending area BA. The buffer member 431 may be disposed in an area of the display panel 130 that does not overlap the back plate 140 to protect the display panel 130 instead of the back plate 140. For example, in the display device 400 according to still another example implementation, the buffer member 431 is disposed on the display panel 130 exposed in the bending area BA to more effectively absorb the external impact.

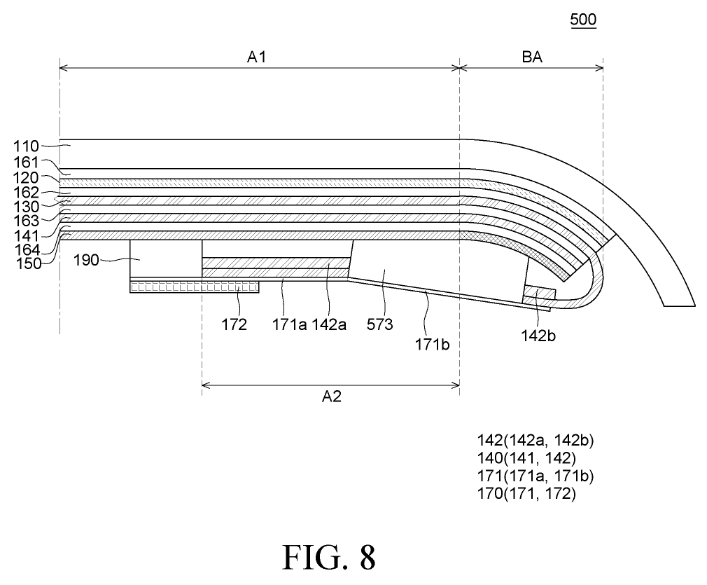

FIG. 8 is a cross-sectional view of a display device according to still another implementation. The only difference between a display device 500 of FIG. 8 and the display device 100 of FIGS. 3A and 3B is a shape of a dam 573, but other components are substantially the same, so that a redundant description will be omitted.

Referring to FIG. 8, a top surface of the dam 573 may be in contact with a rear surface of the metal plate 150. For example, the top surface of the dam 573 may be formed of a curved surface. In this case, the radius of curvature of the top surface of the dam 573 may be the same as the radius of curvature of the bending area BA. For example, the radius of curvature of the rear surface of the metal plate 150 disposed in the bending area BA is also the same as the radius of curvature of the bending area BA so that the top surface of the dam 573 may be disposed to be engaged with the rear surface of the metal plate 150. Accordingly, it is possible to more effectively block the reinforcement member 180 from flowing from the bending area BA to the outside of the area in which the dam 573 is disposed. Accordingly, the dam 573 may minimize the increase in bending stress due to the over-spread or over-expansion of the reinforcement member 180 in the bending area BA.

In the display device 500 according to still another example implementation, the reinforcement member 180 may be disposed in the bending area BA. For example, the reinforcement member 180 fills the empty space of the bending area BA so that the bending stress according to the difference between the curvature direction of the four surfaces and the curvature direction of the bending area BA may be alleviated. In this case, the reinforcement member 180 may be formed of a foaming agent including a plurality of pores. Accordingly, it is possible to minimize the deformation of the bending area BA by absorbing an external impact through a plurality of pores.

Further, in the display device 500 according to still another example implementation, a plurality of dams 573 for guiding the reinforcement member 180 may be disposed on the flexible circuit board 170. For example, the dam 573 may control the arrangement region of the reinforcement member 180 to minimize the overflow and the over-expansion of the reinforcement member 180. In this case, the dam 573 may be disposed only in a part of the bending area BA. Accordingly, the reinforcement member 180 may also be disposed only in a part of the bending area BA. For example, in the display device 500 according to still another implementation, while minimizing the occurrence of an inflection point in the radius of curvature as the reinforcement member 180 partially fills the empty space of the bending area BA, the reinforcement member 180 is not disposed in the entire bending area BA, thereby preventing an increase in bending stress due to over-expansion.

Specifically, in the display device 500 according to still another example implementation, the top surface of the dam 573 is in contact with the rear surface of the metal plate 150 to prevent the reinforcement member 180 from overflowing to the outside of the dam 573. Specifically, the top surface of the dam 573 may be formed of a curved surface having a radius of curvature equal to that of the bending area BA. Accordingly, the rear surface of the metal plate 150 disposed in the bending area BA and the top surface of the dam 573 may be disposed to be engaged with each other. Accordingly, it is possible to block the reinforcement member 180 from flowing from the bending area BA to the outside of the area in which the dam 573 is disposed. Therefore, in the display device 500 according to still another implementation, the arrangement region of the reinforcement member 180 may be more effectively controlled.

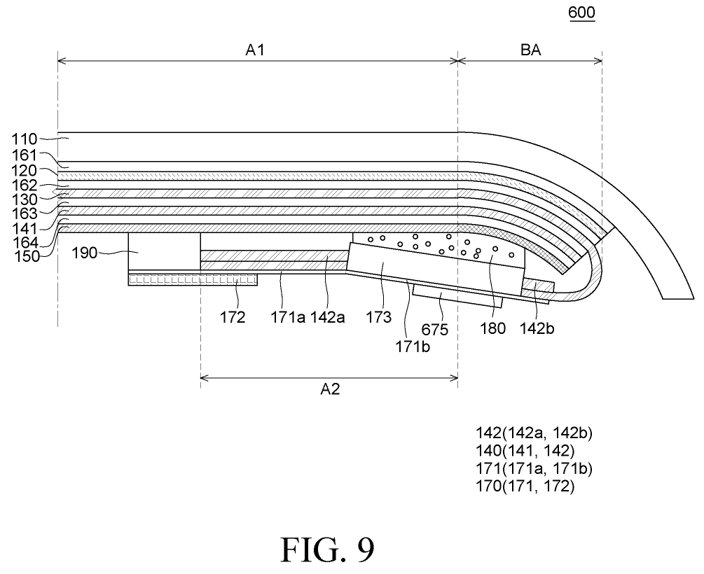

FIG. 9 is a cross-sectional view of a display device according to still another implementation. The only difference between a display device 600 of FIG. 9 and the display device 100 of FIGS. 3A and 3B is the presence or absence of a reinforcement plate 675, but other components are substantially the same, so that a redundant description will be omitted.

Referring to FIG. 9, a reinforcement plate 675 may be disposed on the rear surface of the base substrate 171 of the flexible circuit board 170. The reinforcement plate 675 supports the display panel 130 to minimize deformation of the bending area BA due to external impact. For example, the reinforcement plate 675 may be disposed on a side opposite to the plurality of dams 173 and the reinforcement member 180 with respect to the flexible circuit board 170. Therefore, the reinforcement plate 675 may alleviate an external impact applied to the display panel 130 in an area in which the plurality of dams 173 and the reinforcement member 180 are not disposed.

For example, the reinforcement plate 675 may be formed of the same material as the plurality of dams 173, but is not limited thereto.

In the display device 600 according to still another example implementation, the reinforcement member 180 may be disposed in the bending area BA. For example, the reinforcement member 180 fills the empty space of the bending area BA so that the bending stress according to the difference between the curvature direction of the four surfaces and the curvature direction of the bending area BA may be alleviated. In this case, the reinforcement member 180 may be formed of a foaming agent including a plurality of pores. Accordingly, it is possible to minimize the deformation of the bending area BA by absorbing an external impact through a plurality of pores.

Further, in the display device 600 according to still another example implementation, a plurality of dams 173 for guiding the reinforcement member 180 may be disposed on the flexible circuit board 170. For example, the dam 173 controls the arrangement region of the reinforcement member 180 to minimize the overflow and the over-expansion of the reinforcement member 180. In this case, the dam 173 may be disposed only in a part of the bending area BA. Accordingly, the reinforcement member 180 may also be disposed only in a part of the bending area BA. For example, in the display device 600 according to still another implementation, while minimizing the occurrence of an inflection point in the radius of curvature as the reinforcement member 180 partially fills the empty space of the bending area BA, the reinforcement member 180 is not disposed in the entire bending area BA, thereby preventing an increase in bending stress due to over-expansion.

In particular, in the display device 600 according to still another implementation, the reinforcement plate 675 may be disposed on the rear surface of the flexible circuit board 170. The reinforcement plate 675 may be disposed on a side opposite to the plurality of dams 173 and the reinforcement member 180 with respect to the flexible circuit board 170. Therefore, the reinforcement plate 675 may alleviate an external impact applied to the display panel 130 in an area in which the plurality of dams 173 and the reinforcement member 180 are not disposed. Accordingly, in the display device 600 according to still another example implementation, deformation of the bending area BA due to external impact may be more effectively reduced.

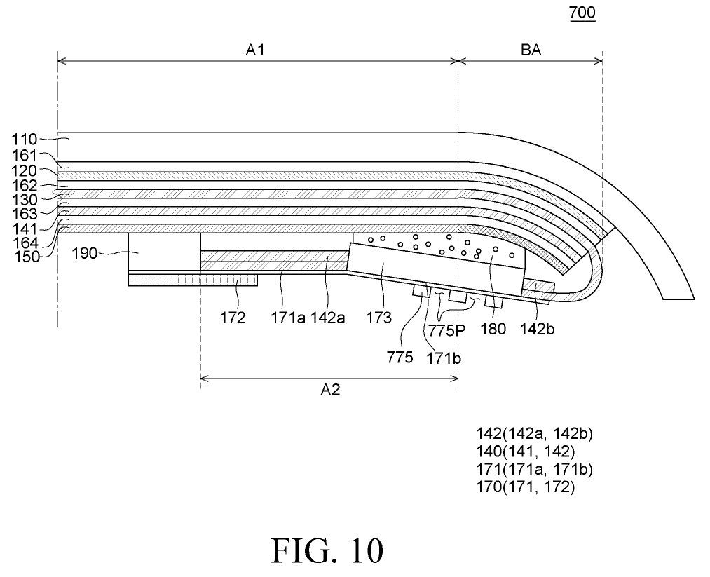

FIG. 10 is a cross-sectional view of a display device according to another implementation. The only difference between a display device 700 of FIG. 10 and the display device 600 of FIG. 9 is a shape of a reinforcement plate 775, but other components are substantially the same, so that a redundant description will be omitted.

Referring to FIG. 10, a reinforcement plate 775 may be disposed on the rear surface of the base substrate 171 of the flexible circuit board 170. The reinforcement plate 775 supports the display panel 130 to minimize deformation of the bending area BA due to external impact. For example, the reinforcement plate 775 may be disposed on a side opposite to the plurality of dams 173 and the reinforcement member 180 with respect to the flexible circuit board 170. Therefore, the reinforcement plate 775 may alleviate an external impact applied to the display panel 130 in an area in which the plurality of dams 173 and the reinforcement member 180 are not disposed.

The reinforcement plate 775 may include a plurality of slit patterns 775P. For example, the plurality of slit patterns 775P may be formed by partially removing the reinforcement plate 775. The plurality of slit patterns 775P facilitates bending of the reinforcement plate 775, thereby reducing bending stress.

In the display device 700 according to still another example implementation, the reinforcement member 180 may be disposed in the bending area BA. For example, the reinforcement member 180 fills the empty space of the bending area BA so that the bending stress according to the difference between the curvature direction of the four surfaces and the curvature direction of the bending area BA may be alleviated. In this case, the reinforcement member 180 may be formed of a foaming agent including a plurality of pores. Accordingly, it is possible to minimize the deformation of the bending area BA by absorbing an external impact through a plurality of pores.

Further, in the display device 700 according to still another example implementation, a plurality of dams 173 for guiding the reinforcement member 180 may be disposed on the flexible circuit board 170. For example, the dam 173 controls the arrangement region of the reinforcement member 180 to minimize the overflow and the over-expansion of the reinforcement member 180. In this case, the dam 173 may be disposed only in a part of the bending area BA. Accordingly, the reinforcement member 180 may also be disposed only in a part of the bending area BA. For example, in the display device 700 according to still another implementation, while minimizing the occurrence of an inflection point in the radius of curvature as the reinforcement member 180 partially fills the empty space of the bending area BA, the reinforcement member 180 is not disposed in the entire bending area BA, thereby preventing an increase in bending stress due to over-expansion.

Further, in the display device 700 according to still another implementation, the reinforcement plate 775 may be disposed on the rear surface of the flexible circuit board 170. The reinforcement plate 775 may be disposed on a side opposite to the plurality of dams 173 and the reinforcement member 180 with respect to the flexible circuit board 170. Therefore, the reinforcement plate 775 may alleviate an external impact applied to the display panel 130 in an area in which the plurality of dams 173 and the reinforcement member 180 are not disposed.

In particular, in the display device 700 according to still another example implementation, the reinforcement plate 775 may include a plurality of slit patterns 775P. The plurality of slit patterns 775P facilitates bending of the reinforcement plate 775, thereby reducing bending stress. Accordingly, in the display device 700 according to still another example implementation of the present disclosure, deformation of the bending area BA due to external impact may be more effectively reduced.

The example implementations of the present disclosure can also be described as follows:

According to an aspect of the present disclosure, there is provided a display device. The display device includes a display panel including a first area, a bending area surrounding the first area, and a second area extending from the bending area, a first back plate disposed below the display panel in the first area and the bending area, a second back plate spaced apart from the first back plate and disposed on the display panel in the bending area and the second area, a flexible circuit board disposed below the display panel in the bending area and the second area, a plurality of dams disposed on the flexible circuit board, and a reinforcement member disposed between the plurality of dams on the flexible circuit board.

The flexible circuit board may include a base substrate including a first part in which a driving circuit is disposed and a second part in which the plurality of dams are disposed.

The plurality of dams may be disposed on two sides of the base substrate so as to face each other in a direction perpendicular to a bending direction of the bending area.

The second back plate may include an opening disposed to overlap the flexible circuit board in the bending area and the second area, and a width of the opening of the second back plate may be equal to a gap between the plurality of dams.

The reinforcement member may be disposed in the opening of the second back plate.

The opening of the second back plate may be disposed between the plurality of dams, and the plurality of dams and the second back plate may be disposed to surround at least a portion of the reinforcement member.

The reinforcement member may be disposed in the second area and the bending area, and the reinforcement member may be disposed in an area excluding at least a partial area of the bending area.

The thickness of each of the plurality of dams may be greater than the sum of the thicknesses of the display panel and the second back plate.

The display device may further include a metal plate disposed below the first back plate. The reinforcement member may be in contact with a rear surface of the metal plate, and the plurality of dams may be disposed to be spaced apart from the rear surface of the metal plate.

The reinforcement member may be formed of a microcapsule-type foaming agent, and the microcapsule-type foaming agent may include a liquid hydrocarbon disposed inside a shell of a thermoplastic resin.

The display device may further comprise an adhesive layer disposed between the first back plate and the display panel and between the second back plate and the display panel, wherein the adhesive layer may be formed of a variable adhesive material.

The second back plate may include a 2-1 back plate disposed in the second area, and a 2-2 back plate disposed in the bending area, the 2-1 back plate and the 2-2 back plate are disposed to be spaced apart from each other based on the opening of the second back plate. The display device may further include an auxiliary dam disposed on the 2-2 back plate.

The display device may further comprise a metal plate disposed under the first back plate, wherein a top surface of the auxiliary dam may be in contact with a rear surface of the metal plate.

The top surface of the auxiliary dam may be formed of a curved surface, and a radius of curvature of the top surface of the auxiliary dam may be the same as a radius of curvature of the rear surface of the metal plate.

The display device may further include a buffer member disposed on the display panel in the bending area. The buffer member may be disposed in an area between the first back plate and the second back plate.

The flexible circuit board further includes a reinforcement plate disposed on a rear surface of the base substrate, and the reinforcement plate may be formed of the same material as the plurality of dams.

The reinforcement plate may include a plurality of slit patterns.

The display device may further comprise a metal plate disposed below the first back plate, wherein top surfaces of the plurality of dams may be in contact with a rear surface of the metal plate.

The top surfaces of the plurality of dams may be formed of curved surfaces, and a radius of curvature of the top surfaces of the plurality of dams may be the same as a radius of curvature of the rear surface of the metal plate.

Although the example implementations of the present disclosure have been described in detail with reference to the accompanying drawings, the present disclosure is not limited thereto and may be embodied in various forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described implementations are illustrative in all aspects and do not limit the present disclosure.

What is claimed is:

1. A display device, comprising:
a display panel including a first area, a bending area around the first area, and a second area extending from the bending area;
a first back plate disposed below the display panel in the first area and in the bending area;
a second back plate spaced apart from the first back plate and disposed below the first back plate in the bending area and in the second area;
a flexible circuit board disposed below the display panel in the bending area and in the second area;
a plurality of dams disposed on the flexible circuit board; and
a reinforcement member disposed between the plurality of dams on the flexible circuit board.

2. The display device according to claim 1, wherein the flexible circuit board includes a base substrate including a first part in which a driving circuit is disposed and a second part in which the plurality of dams is disposed.

3. The display device according to claim 2, wherein the plurality of dams are disposed on two sides of the base substrate so as to face each other in a direction perpendicular to a bending direction of the bending area.

4. The display device according to claim 1, wherein the second back plate includes an opening disposed to overlap the flexible circuit board in the bending area and the second area, and
wherein a width of the opening of the second back plate is equal to a gap between the plurality of dams.

5. The display device according to claim 4, wherein the reinforcement member is disposed in the opening of the second back plate.

6. The display device according to claim 5, wherein the opening of the second back plate is disposed between the plurality of dams, and
wherein the plurality of dams and the second back plate are disposed so as to enclose at least a part of the reinforcement member.

7. The display device according to claim 1, wherein the reinforcement member is disposed in the second area and in the bending area, and
wherein the reinforcement member is disposed in an area excluding at least a partial area of the bending area.

8. The display device according to claim 1, wherein a thickness of each of the plurality of dams is greater than a sum of thicknesses of the display panel and the second back plate.

9. The display device of claim 1, further comprising:
a metal plate disposed below the first back plate,
wherein the reinforcement member is in contact with a rear surface of the metal plate, and
wherein the plurality of dams are disposed to be spaced apart from the rear surface of the metal plate.

10. The display device according to claim 1, wherein the reinforcement member is formed of a microcapsule-type foaming agent, and
wherein the microcapsule-type foaming agent includes a liquid hydrocarbon disposed inside a shell of a thermoplastic resin.

11. The display device according to claim 1, further comprising:
an adhesive layer disposed between the first back plate and the display panel and between the second back plate and the display panel,
wherein the adhesive layer is formed of a variable adhesive material.

12. The display device according to claim 4, wherein the second back plate includes a 2-1 back plate disposed in the second area and a 2-2 back plate disposed in the bending area, the 2-1 back plate and the 2-2 back plate are disposed to be spaced apart from each other based on the opening of the second back plate, and
wherein the display device further includes an auxiliary dam disposed on the 2-2 back plate.

13. The display device of claim 12, further comprising:
a metal plate disposed below the first back plate,
wherein a top surface of the auxiliary dam is in contact with a rear surface of the metal plate.

14. The display device according to claim 13, wherein the top surface of the auxiliary dam comprises a curved surface, and
wherein a radius of curvature of the curved surface of the auxiliary dam is the same as a radius of curvature of the rear surface of the metal plate.

15. The display device according to claim 1, further comprising:
a buffer member disposed on the display panel in the bending area,
wherein the buffer member is disposed in an area between the first back plate and the second back plate.

16. The display device according to claim 2, wherein the flexible circuit board further includes a reinforcement plate disposed on a rear surface of the base substrate, and
wherein the reinforcement plate is formed of the same material as the plurality of dams.

17. The display device according to claim 16, wherein the reinforcement plate includes a plurality of slit patterns.

18. The display device according to claim 1, further comprising:
a metal plate disposed below the first back plate,
wherein top surfaces of the plurality of dams are in contact with a rear surface of the metal plate.

19. The display device according to claim 18, wherein the top surfaces of the plurality dams comprise curved surfaces, and a radius of curvature of the curved surfaces of the plurality of dams is the same as a radius of curvature of the rear surface of the metal plate.
